(19) United States
(12) Patent Application Publication
(10) Pub. No.: US 2025/0311249 A1
(43) Pub. Date: Oct. 2, 2025

(54) Chip Heat Dissipation Integrated Packaging Module

(71) Applicant: RICHTEK TECHNOLOGY CORP., Hsinchu County (TW)

(72) Inventors: Lung-Sheng Lin, Hsinchu County (TW); Heng-Chi Huang, Hsinchu County (TW); Chih-Feng Huang, Hsinchu County (TW); YongZhong Hu, Hsinchu County (TW)

(21) Appl. No.: 18/800,141

(22) Filed: Aug. 12, 2024

Related U.S. Application Data
(60) Provisional application No. 63/570,779, filed on Mar. 27, 2024.

(30) Foreign Application Priority Data
Jun. 19, 2024 (TW) 113122697

(51) Int. Cl. H01L 23/367; H01L 23/00; H01L 23/31; H01L 23/498; H01L 23/538; H01L 25/16

(52) U.S. Cl. CPC H10D 1/20; H01L 23/367; H01L 23/49811; H01L 25/16; H01L 23/3107; H01L 23/538; H01L 24/32

(57) ABSTRACT

An integrated packaging module includes an integrated circuit packaging module and an inductor. The integrated circuit packaging module includes a substrate, a chip, a block terminal and an encapsulation material. The chip is disposed on the substrate and is connected to the substrate in a flip-chip manner, with the back of the chip facing upward. The block terminal is disposed on the base substrate. The encapsulation material covers the substrate and exposes the back of the chip and the upper surface of the block terminal. The inductor is disposed above the integrated circuit packaging module and includes an electrical contact coupled to the block terminal.

### CROSS REFERENCE TO RELATED APPLICATIONS

This application claims the benefit of U.S. Provisional Application No. 63/570,779, filed on Mar. 27, 2024. The content of the application is incorporated herein by reference.

### BACKGROUND OF THE INVENTION

### 1. Field of the Invention

The invention relates to packaging, and in particular, to an integrated packaging module.

### 2. Description of the Prior Art

Packaging is a technology that encapsulates semiconductor devices to protect fragile components from the external environment, and serves to provide mechanical support, receive input signals and transmit output signals.

In the conventional method, components are placed separately, that is, the chip and external components (such as inductors) are placed horizontally on the substrate. Unfortunately, this approach takes up more substrate area, and transmitting current to the external components through a horizontal current path increases power consumption. Furthermore, in the conventional approach, the chip is covered with epoxy molding compound (EMC), resulting in poor heat dissipation of the chip.

### SUMMARY OF THE INVENTION

According to an embodiment of the invention, an integrated packaging module includes an integrated circuit packaging module and an inductor. The integrated circuit packaging module includes a substrate, a chip, a block terminal and an encapsulation material. The chip is disposed on the substrate and is connected to the substrate in a flip-chip manner, with the back of the chip facing upward. The block terminal is disposed on the base substrate. The encapsulation material covers the substrate and exposes the back of the chip and the upper surface of the block terminal. The inductor is disposed above the integrated circuit packaging module and includes an electrical contact coupled to the block terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an integrated circuit packaging component according to an embodiment of the present invention.

FIG. 2 is a schematic diagram of an integrated circuit packaging module according to an embodiment of the present invention.

FIG. 3 is a schematic diagram of another integrated circuit packaging module according to an embodiment of the present invention.

FIG. 4 is a schematic diagram of an integrated packaging module according to an embodiment of the present invention.

FIG. 5 shows a top view of the integrated packaging module in FIG. 4.

FIG. 6 is a schematic diagram of using a single phase inductor in an integrated packaging module according to an embodiment of the present invention.

FIG. 7 shows a schematic cross-sectional view of the integrated packaging module in FIG. 5.

FIG. 8A is a schematic diagram of a cladding metal according to an embodiment of the present invention.

FIG. 8B is a schematic diagram of a cladding metal according to another embodiment of the present invention.

FIG. 8C is a schematic diagram of a cladding metal according to another embodiment of the present invention.

FIG. 9A is a schematic diagram of a cladding metal according to another embodiment of the present invention.

FIG. 9B shows a bottom view of the cladding metal in FIG. 9A.

### DETAILED DESCRIPTION

FIG. 1 is a schematic diagram of an integrated circuit packaging component 1 according to an embodiment of the present invention. The integrated circuit packaging component 1 includes a substrate S, a first chip C1, a second chip C2, a first block terminal T1, a second block terminal T2, a third block terminal T3, a fourth block terminal T4 and a plurality of passive components P. The first chip C1 and the second chip C2 are disposed on the substrate S and are connected to the substrate S using a flip-chip method. The flip-chip method involves connecting the chip to solder bumps, and then flipping the chip over to connect the bumps to the substrate. After flip-chip bonding, the first chip C1 and the second chip C2 are flipped and connected to the substrate S so that the backs of the first chip C1 and the second chip C2 face upward. The backs of the first chip C1 and the second chip C2 may be covered by a metal layer to enhance heat conduction. The block terminals T1-T4 are disposed on the substrate S. The block terminals T1-T4 may be part of the substrate or independent components. The block terminals T1-T4 are made of metal material having high electrical conductivity and low impedance such as copper or copper alloy. The plurality of passive components P are disposed on the substrate S, and the passive components P may be resistors or capacitors. While the embodiment involves two chips and four block terminals, the invention is not limited to this configuration. Other embodiments may have different quantities of chip and block terminal. The quantities of chips and block terminals may be positive integers greater than or equal to one.

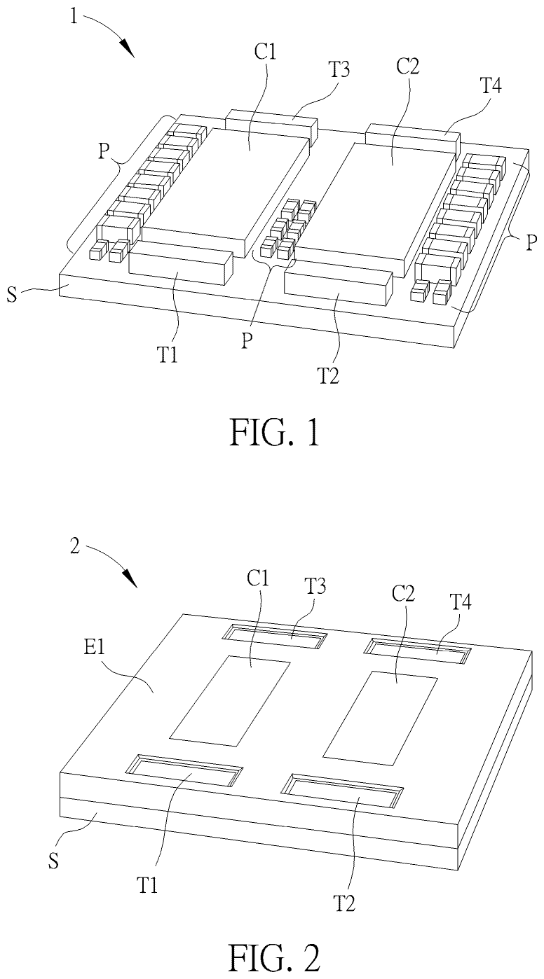

FIG. 2 is a schematic diagram of an integrated circuit packaging module 2 according to an embodiment of the present invention. The integrated circuit packaging module 2 is formed by covering the integrated circuit packaging component 1 in FIG. 1 with the encapsulation material E1. The encapsulation material E1 may be polymer or liquid epoxy resin. The encapsulation material E1 covers the substrate S, the sides of the first chip C1, the sides of the second chip C2, and the sides of the block terminals T1-T4. As shown in FIG. 2, a portion of the back of the first chip C1 and a portion of the back of the second chip C2 and the upper surfaces of the block terminals T1-T4 are exposed. That is, a portion of the back of the first chip C1 and a portion of the back of the second chip C2 and the upper surfaces of the block terminals T1-T4 are not covered by the encapsulation material E1. In some embodiments, underfill technology may be used to cover the integrated circuit packaging component 1. The underfill technology involves applying the encapsulation material to the edge of the chip, enabling the encapsulation material to penetrate into the bottom of the flip-chip chip (the side in contact with the substrate S), and then solidifying by heat. By using the underfill technology, the encapsulation material E1 may only cover the bottoms of the first chip C1 and the second chip C2, but not the sides of the first chip C1, the second chip C2 and the block terminals T1-T4. Regardless of technology being used for covering, the encapsulation material E1 may expose at least half of the back of the first chip C1, half of the back of the second chip C2 and the upper surfaces of the block terminals T1-T4. As shown in FIG. 2, the encapsulation material E1 forms openings on the back of the first chip C1 and the back of the second chip C2 respectively, and the openings may be 50%-100% of the back areas of the chips. That is, the area of the opening on the first chip C1 may be 50%-100% of the back area of the first chip C1, and the area of the opening on the second chip C2 may be 50%-100% of the back area of the second chip C2. If underfill technology is used, the encapsulation material E1 may expose the entire back of the first chip C1 and the entire back of the second chip C2, that is, the opening areas are 100% of the back areas of the chips. Exposing at least half of the chip's back improves heat dissipation. Exposing the upper surfaces of the block terminals allows connections of the block terminals to external components, and the external components may be inductors.

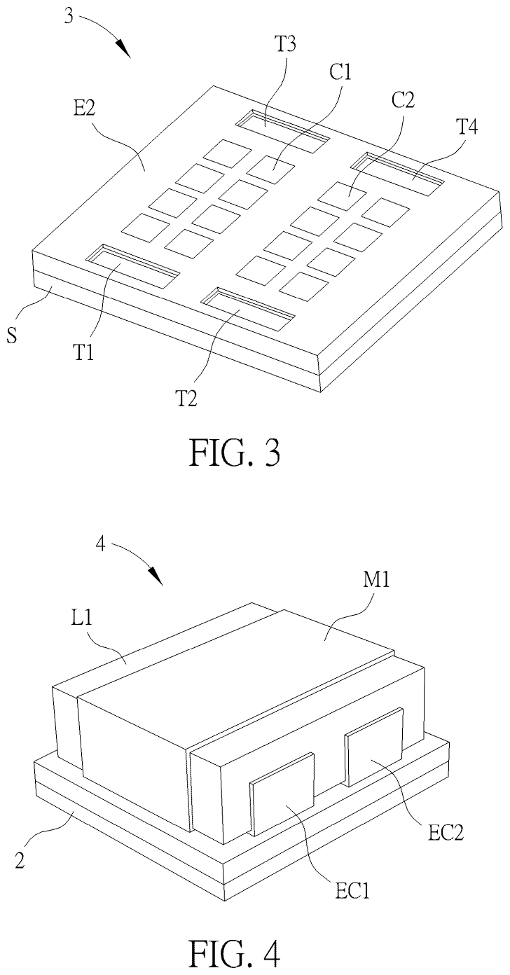

FIG. 3 is a schematic diagram of another integrated circuit packaging module 3 according to an embodiment of the present invention. As shown in FIG. 3, the integrated circuit packaging module 3 is formed by covering the integrated circuit packaging component 1 in FIG. 1 with an encapsulation material E2. The encapsulation material E2 may be polymer or liquid epoxy resin. Unlike the single openings formed by the encapsulation material E1 on the backs of the first chip C1 and the second chip C2 (FIG. 2), the encapsulation material E2 forms a plurality of openings on the back of the first chip C1 and the back of the second chip C2 respectively, exposing at least half of the back of the first chip C1 and, the back of the second chip C2, and exposing the upper surfaces of block terminals T1-T4. The total area of the opening on the first chip C1 may be 50%-100% of the back area of the first chip C1, and the total area of the opening on the second chip C2 may be 50%-100% of the back area of the second chip C2. Compared with the single openings on the backs of the first chip C1 and the second chip C2, forming a plurality of openings on the back of the first chip C1 and the back of the second chip C2 respectively with the encapsulation material E2 may simplify soldering, and result in relatively uniform voids during the soldering process.

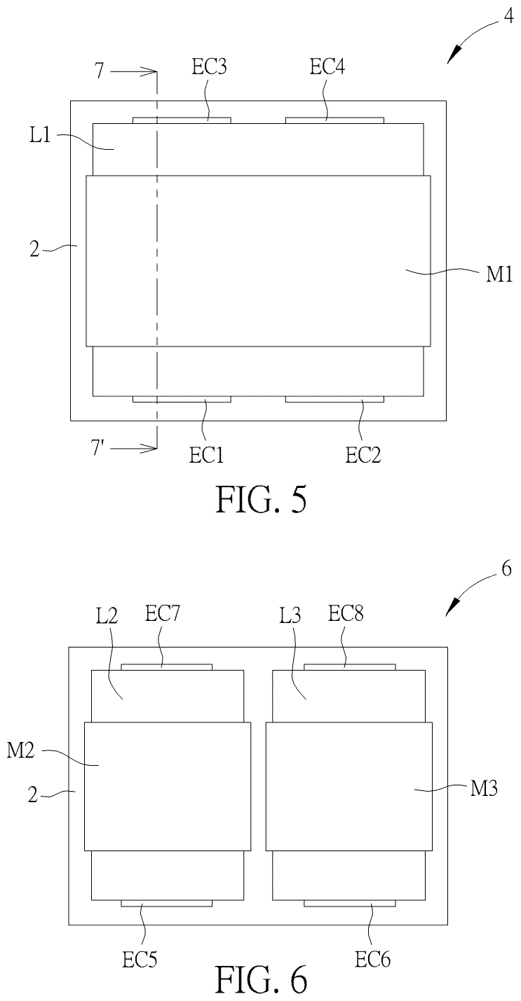

FIG. 4 is a schematic diagram of an integrated packaging module 4 according to an embodiment of the present invention. The integrated packaging module 4 is formed by disposing an inductor L1 above the integrated circuit packaging module 2 in FIG. 2. In some embodiments, the integrated circuit packaging module 2 may be replaced by the integrated circuit packaging module 3. The integrated packaging module 4 may include a cladding metal M1. The cladding metal M1 is a highly thermally conductive material with a thermal conductivity greater than 100 W/mK, and the thickness of the cladding metal M1 may be greater than 0.2 mm to achieve good thermal conductivity. The cladding metal M1 covers the inductor L1 and contacts the exposed back of the first chip C1 and the exposed back of the second chip C2 to dissipate the heat of the first chip C1 and the second chip C2 through the conduction of the cladding g metal M1. In some embodiments, a heat sink or a fan may be added to the integrated packaging module to improve the heat dissipation. Covering the inductor L1 with the cladding metal M1 and contacting the exposed back of the first chip C1 and the exposed back of the second chip C2 may achieve grounding and shields against electromagnetic interference (EMI). In some embodiments, the cladding metal may be coupled to the exposed backs of the chips using solder material or thermal paste. The surface of the cladding metal M1 can be plated with a metal layer, and the material of the metal layer may be nickel, tin and/or silver. In some embodiments, the cladding metal M1 can be omitted, and the thermally conductive material is used to connect the inductor L1 to the exposed back of the first chip C1 and the exposed back of the second chip C2, and is used to conduct the heat of the first chip C1 and the heat of the second chip C2 to the inductor L1, so as to achieve heat dissipation of the first chip C1 and the second chip C2. The inductor may be a single phase inductor or a multi-phase inductor, and an inductor includes at least one magnetic core and at least one electrical contact. The electrical contact may be a coil of the inductor. In FIG. 4, the inductor L1 is a dual phase inductor including two magnetic cores, and the magnetic cores are wrapped with coils. The coils at both ends of the magnetic core serve as electrical contacts. In the embodiment, the electrical contact EC1 and the electrical contact EC2 are the coils of the inductor L1. FIG. 5 shows a top view of the integrated packaging module 4 in FIG. 4. As shown in FIG. 5, the electrical contacts EC1-EC4 are coils at both ends of the magnetic core, and the electrical contacts EC1-EC4 are coupled to the block terminals T1-T4 respectively. The electrical contacts EC1-EC4 may be coupled to the block terminals T1-T4 respectively using a solder material or silver (Ag) sintering paste material. The integrated packaging module 4 includes the inductor L1 placed vertically on the integrated circuit package module 2. Compared with placing the chip and external components (such as inductors) horizontally on the substrate, the method of the present invention occupies less area of the substrate. As the electrical contacts EC1-EC4 are connected to the exposed upper surfaces of the block terminals T1-T4 using the solder material or the Ag sintering paste material, transmitting the current to the inductor through a horizontal current path is no longer used, thus reducing power consumption. The heat dissipation of the chips may be achieved by contacting the exposed backs of the chips with the cladding metal M1 or by connecting the exposed backs of the chips with the inductor L1 using a thermally conductive material.

FIG. 6 is a schematic diagram of using a single phase inductor in an integrated packaging module according to an embodiment of the present invention. The integrated packaging module 6 is formed by disposing an inductor L2 and an inductor L3 above the integrated circuit packaging module 2 in FIG. 2. In some embodiments, the integrated circuit packaging module 2 may be replaced by the integrated circuit packaging module 3. The integrated packaging module 6 may include a cladding metal M2 and a cladding metal M3. The cladding metal M2 and the cladding metal M3 are highly thermally conductive material with a thermal conductivity greater than 100 W/mK, and the thickness of the cladding metal M2 and the cladding metal M3 may be greater than 0.2 mm respectively to achieve good thermal conductivity. The cladding metal M2 covers the inductor L2 and contacts the exposed back of the first chip C1 to dissipate the heat of the first chip C1 through the conduction of the cladding g metal M2. The cladding metal M3 covers the inductor L3 and contacts the exposed back of the second chip C2 to dissipate the heat of the second chip C2 through the conduction of the cladding g metal M3. In some embodiments, a heat sink or a fan may be added to the integrated packaging module to improve the heat dissipation. Covering the inductors L2 and L3 with the cladding metals M2 and M3 respectively and contacting the exposed back of the first chip C1 and the exposed back of the second chip C2 respectively may achieve grounding and shields against electromagnetic interference (EMI). The surface of the cladding metals M2 and M3 may be plated with a metal layer, and the material of the metal layer may be nickel, tin and/or silver. In some embodiments, the cladding metal M2 and the cladding metal M3 may be omitted, and the thermally conductive material is used to connect the inductor L2 to the exposed back of the first chip C1 and the inductor L3 to the exposed back of the second chip C2, and is used to conduct the heat of the first chip C1 to the inductor L2 and the heat of the second chip C2 to the inductor L3, so as to achieve heat dissipation of the first chip C1 and the second chip C2. In FIG. 6, the inductor L2 and the inductor L3 are both single phase inductors, and each contains a magnetic core wrapped with a coil. The coils at both ends of the magnetic core may serve as electrical contacts. The electrical contact EC5 and the electrical contact EC7 are the coils of the inductor L2, and the electrical contact EC6 and the electrical contact EC8 are the coils of the inductor L3. The electrical contacts EC5-EC8 may be coupled to the block terminals T1-T4 respectively using a solder material or Ag sintering paste material. Compared with using a dual-phase inductor, using two separate single phase inductors may reduce interference by avoiding the mutual interference of magnetic cores and coils within the inductor. While this embodiment involves two chips and four block terminals, the invention is not limited thereto this configuration. In other embodiments, the number of chips and terminals may vary, and the number of inductors may also vary. The effect of multi-phase inductor may also be achieved by combining different numbers of single phase inductors or multi-phase inductors.

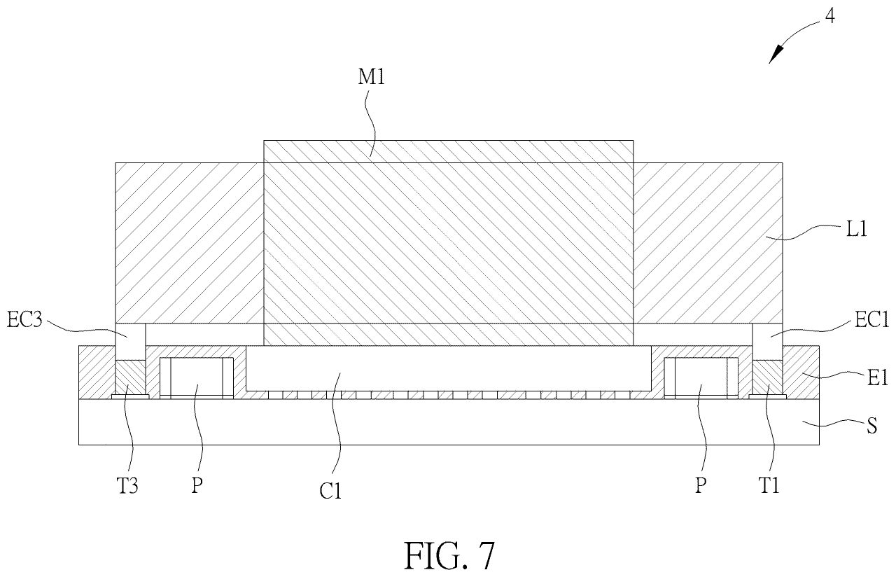

FIG. 7 shows a schematic cross-sectional view of the integrated packaging module 4 taken along the section line 7-7′ in FIG. 5. As shown in FIG. 7, the integrated packaging module 4 includes a substrate S, a first chip C1 disposed on the substrate S and is connected to the substrate S in a flip-chip manner. The block terminal T1, the block terminal T3 and the plurality of passive components P are disposed on the substrate S. The encapsulation material E1 is on the substrate S, covering the sides of the first chip C1 and the sides of the block terminals T1 and T3, and the exposed back of the first chip C1 and the upper surfaces of the block terminals T1 and T3 are not covered by the encapsulation material E1. The cladding metal M1 covers the inductor L1 and contacts the exposed back of the first chip C1. In some embodiments, the cladding metal may be coupled to the exposed back of the chip using the solder material. The electrical contacts EC1 and EC3 may be connected to the block terminals T1 and T3 respectively using a solder material or Ag sintering paste material. As shown in FIG. 7, the upper surfaces of the block terminals T1 and T3 may be slightly lower than the surface of the encapsulation material E1, and the electrical contacts EC1 and EC3 may form pins that are inserted into the openings of the encapsulation material E1 and coupled to the block terminals T1 and T3. This arrangement may help to secure the inductor L1. By adjusting the heights of the pins, the cladding metal M1 may easily make contact with the exposed back of the first chip C1. In some embodiments, the cladding metal M1 may be omitted, and the thermally conductive material may be used to connect the exposed back of the first chip C1 and the inductor L1.

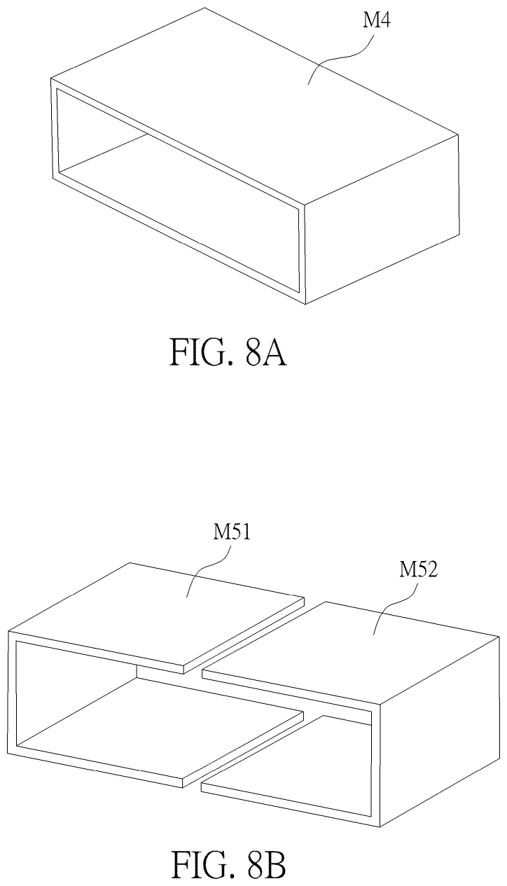

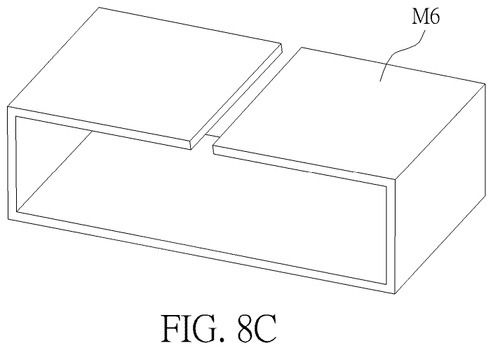

FIG. 8A is a schematic diagram of a cladding metal M4 according to an embodiment of the present invention. As shown in FIG. 8A, the cladding metal M4 forms a rectangular ring shape. The cladding metal may be in various shapes. The cladding metals in the embodiments in FIG. 4-7 are all based on the style in FIG. 8A, but the invention is not limited thereto. FIG. 8B is a schematic diagram of a cladding metal M51 and M52 according to another embodiment of the present invention. As shown in FIG. 8B, the cladding metal comprises two symmetrical U-shaped pieces M51 and M52. FIG. 8C is a schematic diagram of a cladding metal M6 according to another embodiment of the present invention. As shown in FIG. 8C, the cladding metal M6 has a bent shape.

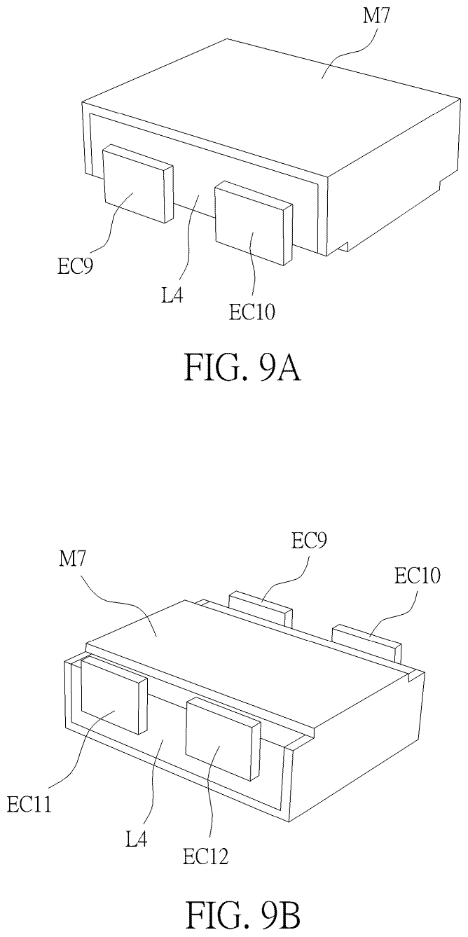

FIG. 9A is a schematic diagram of a cladding metal M7 according to another embodiment of the present invention and FIG. 9B shows a bottom view of the cladding metal M7 in FIG. 9A. As shown in FIG. 9A and FIG. 9B, the inductor L4 is covered by the cladding metal M7. The widths of the cladding metals in FIGS. 8A-8C are all the same in width. In contrast, the cladding metals M7 in FIG. 9A and FIG. 9B may be different in width, and the cladding metals M7 may be enlarged on the sides, top and bottom of the inductor L4 to improve the heat dissipation. The electrical contacts EC9-EC12 are not covered by cladding metal M7. However, the sides, top and bottom of the inductor L4 (excluding the electrical contacts EC9-EC12) may be covered with the cladding metal M7 to achieve better heat dissipation.

The integrated circuit packaging module of the present invention is formed by covering the integrated circuit packaging component with the encapsulation material and the encapsulation material exposes at least half of the back of the chip and exposes the upper surface of the block terminals. The integrated packaging module of the present invention places the inductors vertically on the integrated circuit packaging module. Compared with placing the chip and the inductors horizontally on the substrate, the method of the present invention may occupy less substrate area. Since the electrical contacts are connected to the exposed upper surfaces of the block terminals T1-T4 using the solder material or Ag sintering paste material, the current does not need to be transmitted to the inductor through a horizontal current path, thereby reducing power consumption. By contacting the exposed back of the chip with the cladding metal or connecting the exposed back of the chip with the inductor through a thermally conductive material, the heat of the chip is conducted to either the cladding metal or the inductor via the exposed back of the chip, achieving favorable chip heat dissipation. Furthermore, covering the inductor with cladding metal and contacting the exposed back of the chip allows for grounding and shielding against the electromagnetic interference (EMI).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated packaging module comprising:
an integrated circuit packaging module comprising:
a substrate;
at least one chip disposed on the substrate and connected to the substrate in a flip-chip manner, wherein a back of the at least one chip faces upward;
at least one block terminal disposed on the substrate; and
an encapsulation material covering the substrate and exposing the back of the at least one chip and a upper surface of the at least one block terminal; and
at least one inductor disposed above the integrated circuit packaging module, comprising at least one electrical contact coupled to the at least one block terminal.

2. The integrated packaging module of claim 1, wherein the at least one block terminal is part of the substrate or an independent component.

3. The integrated packaging module of claim 1, further comprising a thermal conductive material connecting the back of the at least one chip and the at least one inductor, the thermal conductive material being configured to conduct heat of the at least one chip to the at least one inductor.

4. The integrated packaging module of claim 1, wherein the encapsulation material covers a side of the at least one chip and a side of the at least one block terminal.

5. The integrated packaging module of claim 1, wherein a material of the at least one block terminal is a metal with high electrical conductivity and low impedance.

6. The integrated packaging module of claim 1, wherein the at least one electrical contact is coupled to the at least one block terminal using a solder material or a silver (Ag) sintering paste material.

7. The integrated packaging module of claim 1, wherein the encapsulation material exposes an entirety of the back of the at least one chip.

8. The integrated packaging module of claim 1, wherein the encapsulation material exposes a portion of the back of the at least one chip.

9. The integrated packaging module of claim 1, wherein the encapsulation material forms a plurality of openings on the back of the at least one chip.

10. The integrated packaging module of claim 1, wherein the inductor is a single phase inductor.

11. The integrated packaging module of claim 1, wherein the inductor is a multi-phase inductor.

12. The integrated packaging module of claim 1, further comprising:
a cladding metal covering the at least one inductor and contacting the back of the at least one chip.

13. The integrated packaging module of claim 12, wherein the cladding metal is coupled to the back of the at least one chip using a solder material or a thermal paste.

14. The integrated packaging module of claim 12, wherein the cladding metal forms a rectangular ring shape.

15. The integrated packaging module of claim 12, wherein the cladding metal comprises two symmetrical U-shaped pieces.

16. The integrated packaging module of claim 12, wherein the cladding metal has a bent shape.

17. The integrated packaging module of claim 12, wherein the cladding metal does not cover the at least one electrical contact.

18. The integrated packaging module of claim 12, wherein a thermal conductivity of the cladding metal is greater than 100 W/mK.

19. The integrated packaging module of claim 12, wherein a thickness of the cladding metal is greater than 0.2 mm.

20. The integrated packaging module of claim 1, wherein the back of the at least one chip is coated using a metal layer.
